(19) United States
(12) Patent Application Publication
(10) Pub. No.: US 2025/0374816 A1
(43) Pub. Date: Dec. 4, 2025

(54) CARBON NANOTUBE DEVICE AND FORMING METHOD THEREOF

(71) Applicants: TAIWAN SEMICONDUCTOR MANUFACTURING COMPANY, LTD., Hsinchu (TW); National Yang Ming Chiao Tung University, Hsinchu City (TW)

(72) Inventors: Chen-Han CHOU, New Taipei City (TW); Chao-Hsin CHIEN, Hsinchu City (TW); Hsin-Yuan CHIU, Kaohsiung City (TW); Kuan-Hsiang CHIU, Hsinchu City (TW); Han-Yi HUANG, New Taipei City (TW); Man-Ling SUN, Changhua County (TW); Guan-Zhen WU, Taichung City (TW)

(73) Assignees: TAIWAN SEMICONDUCTOR MANUFACTURING COMPANY, LTD., Hsinchu (TW); National Yang Ming Chiao Tung University, Hsinchu City (TW)

(21) Appl. No.: 18/675,529

(22) Filed: May 28, 2024

(51) Int. Cl. H10K 71/30; H10K 10/46; H10K 10/84; H10K 85/20

(52) U.S. Cl. CPC H10K 71/30; H10K 10/464; H10K 10/484; H10K 10/84; H10K 85/221

(57) ABSTRACT

A device includes a plurality of nanostructures, a first source/drain contact, a second source/drain contact, a gate electrode, and a solid-state doping layer. The nanostructures are over a substrate. The first source/drain contact is over first source/drain regions of the nanostructures. The second source/drain contact is over second source/drain regions of the nanostructures. The gate electrode is between the first and second source/drain contacts. The solid-state doping layer overlaps with the first source/drain contact.

### BACKGROUND

As the semiconductor industry has progressed into nanometer technology process nodes in pursuit of higher device density, higher performance, and lower costs, challenges from both fabrication and design issues have resulted in the development of three-dimensional designs, such as gate all around (GAA) structures. Non-Si based low-dimensional materials are promising candidates to provide superior electrostatics (e.g., for short-channel effect) and higher performance (e.g., less surface scattering). Carbon nanotubes (CNTs) are considered one such promising candidate due to their high carrier mobility and substantially one dimensional structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a CNTFET in accordance with some embodiments of the present disclosure.

FIG. 2 is a cross-sectional view of the CNTFET illustrated in FIG. 1.

FIG. 3A illustrates a cross-sectional view of a multilayer stack including a solid-state doping layer.

FIGS. 3B-3C are graphs showing experimental results of the multilayer stack as illustrated in FIG. 3A.

FIG. 4A illustrates a cross-sectional view of a pristine CNTFET without a solid-state doping layer.

FIG. 4B illustrates a cross-sectional view of an electrostatically doped CNTFET with a solid-state doping layer.

FIG. 4C is a graph showing experimental results of the pristine CNTFET as illustrated in FIG. 4A and the electrostatically doped CNFFET as illustrated in FIG. 4B.

FIGS. 5A-11D illustrate top views and cross-sectional views of intermediate stages in formation of an example CNTFET in accordance with some embodiments of the present disclosure.

FIGS. 12A-18D illustrate top views and cross-sectional views of intermediate stages in formation of an example CNTFET in accordance with some embodiments of the present disclosure.

FIGS. 19A-21D illustrate top views and cross-sectional views of intermediate stages in formation of an example CNTFET in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Carbon nanotubes (CNTs) having diameters in the order of nm (e.g., about 1 nm) are considered a material of choice for making scaled FET device due to their cylindrical geometry, excellent electrical and mechanical properties. A field effect transistor (FET) using a CNT with a gate length about 10 nm or less shows excellent electrical characteristics. However, a fabrication technology for CNT FET has not been well established.

Silicon-based devices have relied on ion implantation to dope their source/drain (S/D) regions. However, this method may be detrimental to carbon nanotubes (CNTs) due to the strong implantation energy, which can damage the CNTs and impair their transport properties. Conversely, lower energy ion implantation fails to achieve a sufficient doping effect. Therefore, embodiments of the present disclosure relate to an improved doping technique designed for carbon nanotube field-effect transistors (CNTFETs), which addresses the limitations of the foregoing doping methods. In particular, embodiments of the present disclosure use an electrostatic doping technique to induce charge carriers in source/drain regions in the CNTs without implanting dopant atoms into the CNTs. In particular, the electrostatic doping can be achieved by forming one or more dielectric layers in proximity to the CNTs, wherein the one or more dielectric layers are non-stoichiometric and include nitrogen vacancies and/or oxygen vacancies that can induce an electric field around the CNTs and hence induce an n-type electrostatic doping effect in the CNTs.

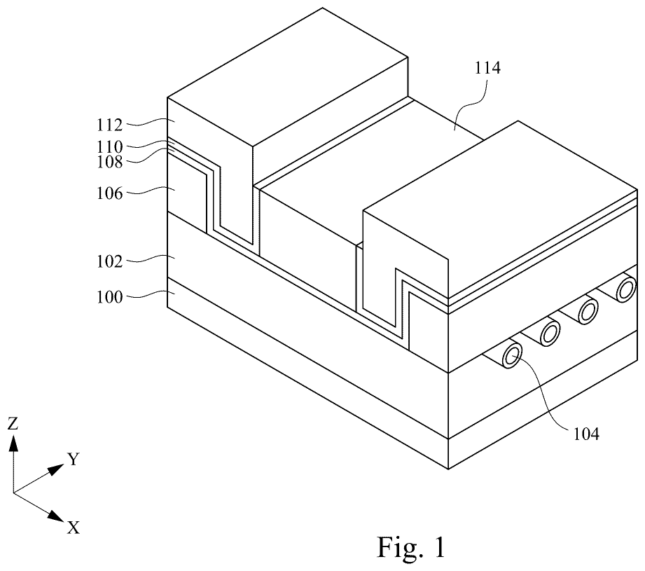

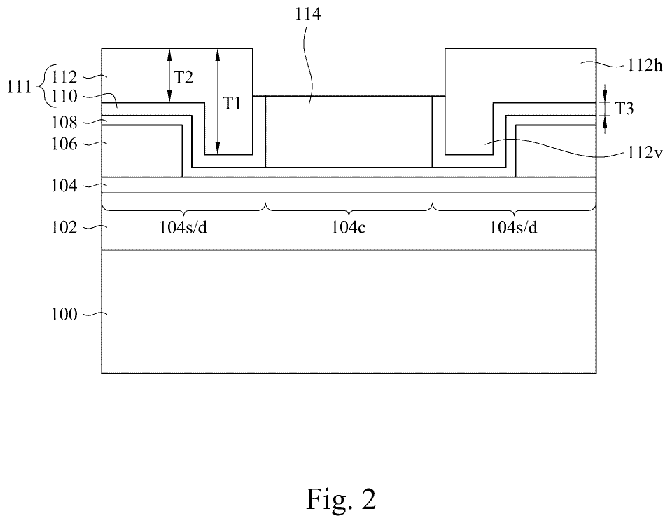

FIG. 1 is a perspective view of a CNTFET in accordance with some embodiments of the present disclosure. FIG. 2 is a cross-sectional view of the CNTFET illustrated in FIG. 1. The CNTFET is formed on a substrate 100. In some embodiments, the substrate 100 may be a semiconductor substrate, such as a bulk semiconductor substrate, a semiconductor-on-insulator (SOI) substrate, a multi-layered or gradient substrate, or the like. The substrate 100 may include a semiconductor material, such as an elemental semiconductor including Si and Ge; a compound or alloy semiconductor including SiC, SiGe, GeSn, GaAs, GaP, GaAsP, AlInAs, AlGaAs, GaInAs, InAs, GaInP, InP, InSb, GaInAsP; a combination thereof, or the like. The substrate 100 may be doped or substantially un-doped. In some embodiments, the substrate 100 may be a sapphire substrate.

A dielectric layer 102 is formed over the substrate 100, and serves to electrically isolate the overlying CNTFETs from the underlying substrate 100. In some embodiments, the dielectric layer 102 is an interlayer dielectric (ILD) layer which include an oxide-based dielectric material, such as silicon oxide (SiOₓ), hafnium oxide (HfOₓ), aluminum oxide (AlOₓ), the like, or combinations thereof. In some embodiments, the dielectric layer 102 has a thickness in a range from about 10 nm to about 1000 nm.

A plurality of carbon nanotubes (CNTs) 104 are disposed over the dielectric layer 102. The CNTs 104 are arranged on the dielectric layer 102 aligned with substantially the same direction (e.g., X direction as illustrated in FIG. 1). The deviation from the x direction of the alignment of the CNTs 104 is about ±12 degrees in some embodiments, and is about ±3 degrees in other embodiments. The CNTs 104 are arranged with a density in a range from about 20 tubes/μm to about 350 tubes/μm along the Y direction in some embodiments. The length of the CNTs 104 (in the X direction) is in a range from about 0.1 μm to about 10 μm in some embodiments. The average diameter of the CNTs 104 is in a range from about 1 nm to about 10 nm in some embodiments. In some embodiments, the CNTs 104 can be formed by various methods, such as arc-discharge or laser ablation methods, or a templated CVD method on a sapphire substrate. The formed CNTs 104 can be dispersed in a solvent, such as sodium dodecyl sulfate (SDS). The CNTs 104 can be transferred to and disposed on the dielectric layer 102 using various methods, such as a floating evaporative self-assembly method in some embodiments. The carbon nanotubes can be interchangeably referred to as nanostructures, one-dimensional (1D) channel structures, nano channel structures, or atomic channel structures.

Source/drain contacts 106 are respectively disposed on source/drain regions 104s/d of each CNT 104. In some embodiments, the source/drain contacts include Pd, Pt, Au, Sc, Y, W, Ti, TiN, the like, or combinations thereof. In some embodiments, the source/drain contacts 106 each have a thickness in a range from about 20 nm to about 1000 nm.

A gate dielectric layer 108 is disposed over a channel region of each CNT 104. In some embodiments, the gate dielectric layer 108 may include an oxide-based dielectric or a nitride-based dielectric. For example, the gate dielectric layer 108 includes SiOₓ, HfOₓ, AlOₓ, YOₓ, ScOₓ, MoOₓ, WOₓ, VOₓ, SiNₓ, HfNₓ, AlNₓ, YNₓ, ScNₓ, the like, or combinations thereof. In some embodiments, the gate dielectric layer 108 has a thickness in a range from about 2 nm to about 100 nm.

Nitride-based dielectric layers 112 are respectively disposed over source/drain regions 104s/d of each CNT 104, serving to induce an electrostatic doping effect on the source/drain regions 104s/d of each CNT 104. In some embodiments, the nitride-based dielectric layers 112 are non-stoichiometric and include nitrogen vacancies, which are sites where nitrogen atoms are missing. The nitride-based dielectric layers with nitrogen vacancies are thus interchangeably referred to as nitrogen-vacancy-containing layers or solid-state doping layers serving for inducing an electrostatic effect on the source/drain regions 104s/d of CNTs 104. These nitrogen vacancies are not merely empty spaces but act as centers of electronic activity. They can trap electrons, leading to the formation of localized charges. This trapping of electrons at the nitrogen vacancy sites creates a dipole moment because there is a separation of charge. This dipole moment, in turn, generates an electric field that extends into the surrounding material, including the underlying source/drain regions 104s/d of CNTs 104. When source/drain regions 104s/d of the CNTs 104 are in proximity to the nitride-based layer 112 with nitrogen vacancies, the electric field generated by the dipoles at the vacancy sites interacts with the electrons in the source/drain regions 104s/d of the CNTs 104. This interaction can lead to an n-type electrostatic doping effect on the source/drain regions 104s/d of CNTs 104. In n-type doping, electrons are added to the conduction band of the material, increasing its conductivity. The electric field emanating from the nitrogen vacancies equivalently “donates” electrons to the source/drain regions 104s/d in the CNTs 104, increasing the electron density in the conduction band within the source/drain regions 104s/d in the CNTs. This process does not involve the physical transfer of dopant atoms into the carbon nanotube's structure, as in the existing ion implantation methods. Instead, it is an electrostatic effect, where the presence of the electric field alters the electronic properties of adjacent regions in the CNTs 104, making them behave as if they had been doped with electron-donating atoms.

In some embodiments, the nitride-based dielectric layer 112 includes a non-stoichiometric nitride material with nitrogen vacancies. For example, the nitride-based dielectric layer 112 may include SiNₓ, HfNₓ, AlNₓ, YNₓ, ScNₓ, the like or combinations thereof. For example, the nitride-based dielectric layer 112 includes non-stoichiometric aluminum nitride where the atomic ratio of aluminum (Al) to nitrogen (N) deviates from the ideal or stoichiometric ratio of 1:1. The non-stoichiometric aluminum nitride can be formed under certain conditions where there is an excess of aluminum or deficiency of nitrogen during the formation process. Techniques such as chemical vapor deposition (CVD), atomic layer deposition (ALD), or physical vapor deposition (PVD) can be optimized to adjust the flow rate ratio of aluminum-containing gas to nitrogen-containing gas, temperature, and pressure to promote the formation of nitrogen vacancies. This imbalance in the atomic ratio of aluminum to nitrogen can lead to the creation of nitrogen vacancies (missing nitrogen atoms) within the non-stoichiometric aluminum nitride, which facilitates inducing the electrostatic doping effect on the source/drain regions 104s/d within the CNTs 104.

In some embodiments, the nitride-based dielectric layer 112 has a maximal thickness T1 in a range from about 2 nm to about 100 nm. The nitride-based dielectric layer 112 has the maximal thickness T1 at a region laterally offset from the source/drain contact 106, and a minimal thickness T2 at a region vertically overlapping the source/drain contact 106. In some embodiments, the minimal thickness T2 is less than the maximal thickness T1. This may be because the nitride-based dielectric layer 112 is not formed in a conformal manner to the underlying materials, so as to increase the total volume of the nitride-based dielectric layer 112, which in turn enhances the electrostatic doping effect in the underlying source/drain regions 104s/d of the CNTs 104. In some embodiments, each nitride-based dielectric layer 112 has a vertical portion 112v extending vertically between the gate electrode 114 and the source/drain contact 106, and a horizontal portion 112h horizontally extending above the source/drain contact 106.

In some embodiments, an oxide-based dielectric layer 110 is disposed between the nitride-based dielectric layer 112 and the corresponding source/drain region 104s/d in the CNT 104. The oxide-based dielectric layer 110 serves to further enhance the electrostatic doping effect and improve the carrier mobility in the source/drain region 104s/d in the CNT 104. In particular, the oxide-based dielectric layer 110 is a non-stoichiometric oxide layer with oxygen vacancies. The oxide-based dielectric layers with oxygen vacancies are thus interchangeably referred to as oxygen-vacancy-containing layers. The oxygen vacancy concentration in the oxide-based dielectric layer 110 may be different from the nitrogen vacancy level in the nitride-based dielectric layer 112. Such discrepancy in vacancy concentrations can result in different charge numbers between the oxide-based dielectric layer 110 and the nitride-based dielectric layer 112, which in net effect enhances the electrostatic doping effect on the CNT 104.

In some embodiments, the oxide-based dielectric layer 110 includes SiOₓ, HfOₓ, AlOₓ, YOₓ, ScOₓ, MoOₓ, WOₓ, VOₓ, the like, or combinations thereof. For example, the oxide-based dielectric 110 may include a non-stoichiometric yttrium oxide (YOₓ) where the atomic ratio of yttrium (Y) to oxygen (O) deviates from the ideal or stoichiometric ratio of 2:3. This imbalance in the atomic ratio of yttrium to oxygen can lead to the creation of oxygen vacancies (missing oxygen atoms) within the non-stoichiometric yttrium oxide, which facilitates enhancing the electrostatic doping effect on the source/drain regions 104s/d within the CNTs 104.

In some embodiments, unlike the non-conformal profile of the nitride-based dielectric layer 112, the oxide-based dielectric layer 110 is a conformal layer having a cross-sectional profile following the underlying surface topography. The oxide-based dielectric layer 110 has a thickness T3 less than the minimal thickness T2 of the nitride-based dielectric layer 112. Such thickness difference allows for forming a sufficient thick nitride-based dielectric layer 112 at a sufficient short distance from the CNT 104, to optimize the electrostatic doping effect. In some embodiments, the oxide-based dielectric layer 110 has the thickness T3 in a range from about 1 angstrom to about 100 nm. In some embodiments, the oxide-based dielectric layer 110 and the nitride-based dielectric layer 112 can be collectively referred to as a dual-layer electrostatic doping stack 111.

A gate electrode 114 is disposed over the gate dielectric layer 108. In some embodiments, the gate electrode 114 includes Pd, Pt, Au, Sc, Y, W, Ti, TiN, the like, or combinations thereof. In some embodiments, the gate electrode 106 has a thickness in a range from about 20 nm to about 1000 nm. The gate electrode 114 is disposed between two dual-layer electrostatic doping stacks 111. Stated differently, the left one of the dual-layer electrostatic doping stacks 111 on the left side of the gate electrode 114 is separated from the right one of the dual-layer electrostatic doping stacks 111, and the gate electrode 114 is free from coverage by any of the dual-layer electrostatic doping stacks 111.

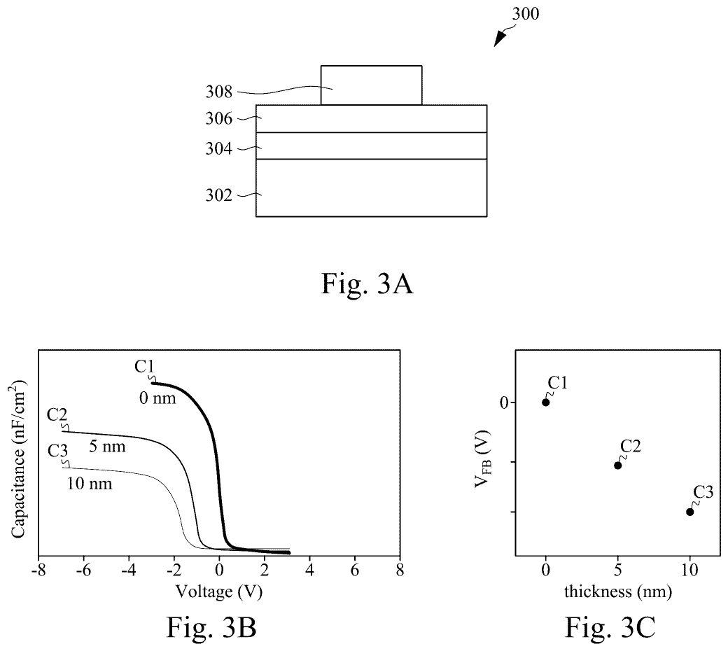

FIGS. 3B-3C are graphs showing experimental results of a multilayer stack 300 as illustrated in FIG. 3A, wherein the multilayer stack includes a p-type substrate 302, an oxide-based barrier layer 304 over the p-type substrate 302, and a nitride-based dielectric layer 306 over the oxide-based barrier layer 302, and a metal electrode 308 over the nitride-based dielectric layer 306. In some embodiments, the oxide-based barrier layer 304 is an yttrium oxide layer with a thickness of about 4.2 nm. The nitride-based dielectric layer 306 is an aluminum nitride layer with nitrogen vacancies. FIG. 3B illustrates capacitance-voltage (C-V) measurements conducted at a frequency of about 1 MHz for the multilayer structure 300 with varying thicknesses of the nitride-based dielectric layer 306. The graph plots capacitance per unit area (in nF/cm²) on the y-axis against applied voltage (in V) on the x-axis. The graph shows three distinct C-V curves C1, C2, and C3 corresponding to the nitride-based dielectric layer 306's thicknesses of 0 nm, 5 nm, and 10 nm, indicating the capacitance across a voltage sweep. FIG. 3C is a graph plotting the flat band voltage (V_{FB}, in V) derived from the C-V curves C1, C2, and C3 against the thickness of nitride-based dielectric layer 306. Theses graphs reveals that as the thickness of the nitride-based dielectric layer 306 increases, the flat band voltage shifts progressively towards more negative values. This observed trend indicates that the nitride-based dielectric layer 306 induces an n-type conductivity behavior in the multilayer stack 300.

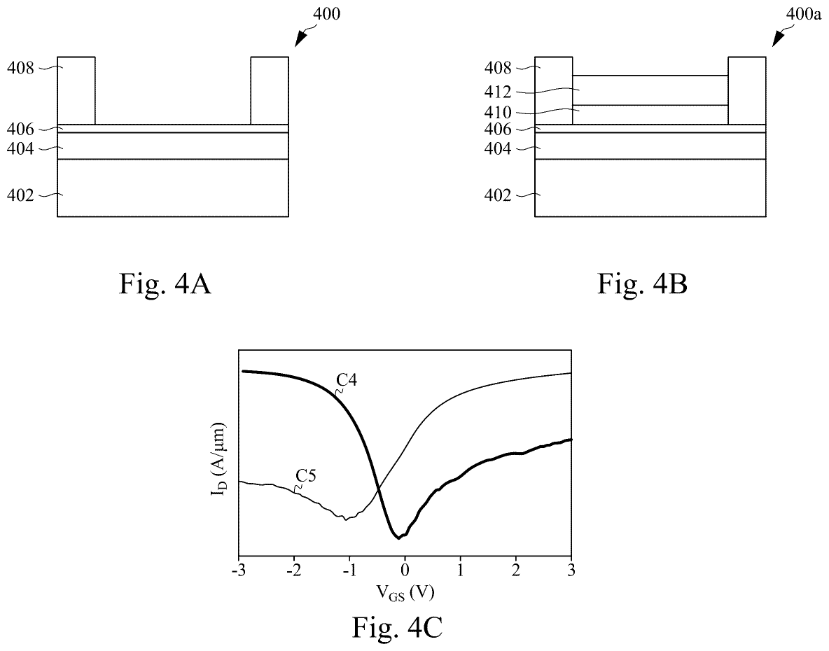

FIG. 4C is a graph showing experimental results of a pristine CNTFET 400 as illustrated in FIG. 4A and an electrostatically doped CNFFET 400a as illustrated in FIG. 4B. The pristine CNTFET 400 includes a substrate 402, a dielectric layer 404 over the substrate 402, one or more CNTs 406 over the dielectric layer 404, and source/drain contacts 408 over the CNTs 406. The electrostatically doped CNTFET 400a generally shares the same structures as the pristine CNTFET 400, except that the electrostatically doped CNTFET 400a further includes an oxide-based dielectric layer 410 with oxygen vacancies and a nitride-based dielectric layer 412 with nitrogen vacancies. In particular, the oxide-based dielectric layer 410 includes an yttrium oxide layer, and the nitride-based dielectric layer 412 includes an aluminum nitride layer. FIG. 4C illustrates current-voltage (I_{D}-V_{GS}) characteristics of these CNTFETs, illustrating the current as a function of gate-source voltage for the pristine CNTFET 400 and the electrostatically doped CNTFET 400a. In particular, the curve C4 represents a current-voltage characteristic of the pristine CNTFET 400, and the curve C5 represents a current-voltage characteristic of the electrostatically doped CNTFET 400a. As illustrated in FIG. 4C, the electrostatic doping effect resulting from the dielectric layers 410, 412 effectively influences the conductivity type of the CNTFET, as indicated by the shift from the pristine I-V curve C4 to the electrostatically doped I-V curve C5. In particular, the pristine CNTFET 400 exhibits a p-type transistor behavior as indicated by the I-V curve C4, whereas the electrostatically doped CNTFET 400a exhibits an n-type transistor behavior as indicated by the I-V curve C5. This alteration in conductivity type is attributed to the induction of n-type charge carriers within the CNTs 406, likely due to the presence of positive charges in the nitride-based dielectric layer 412 arising from nitrogen vacancies. These experimental results show the effectiveness of electrostatic doping in modulating the conductivity type of CNTFETs through strategic incorporation of non-stoichiometric dielectric layers.

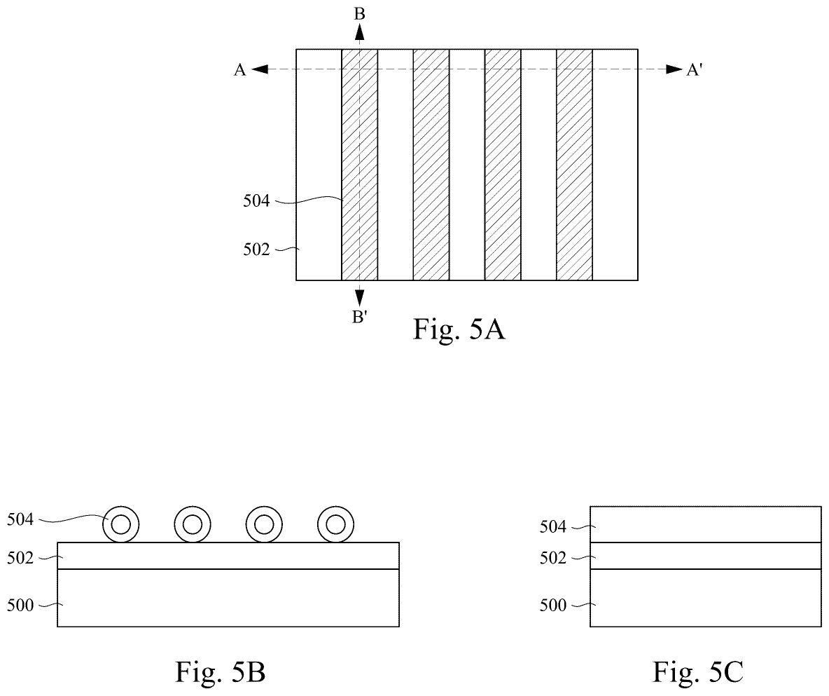

FIGS. 5A-11D illustrate top views and cross-sectional views of intermediate stages in formation of an example CNTFET in accordance with some embodiments of the present disclosure. Although the top views and cross-sectional views shown in FIGS. 5A-11D are described with reference to a method, it will be appreciated that the structures shown in FIGS. 5A-11D are not limited to the method but rather may stand alone separate of the method. Although FIGS. 5A-11D are described as a series of acts, it will be appreciated that these acts are not limiting in that the order of the acts can be altered in other embodiments, and the methods disclosed are also applicable to other structures.

FIG. 5A is a top view of an intermediate stage in manufacturing of a CNTFET, FIG. 5B is a cross-sectional view obtained from cut A-A′ in FIG. 5A, and FIG. 5C is a cross-sectional view obtained from cut B-B′ in FIG. 5A. In FIGS. 5A-5C, a substrate 500 is illustrated. In some embodiments, the substrate 500 may be a semiconductor substrate, such as a bulk semiconductor substrate, a semiconductor-on-insulator (SOI) substrate, a multi-layered or gradient substrate, or the like. The substrate 500 may include a semiconductor material, such as an elemental semiconductor including Si and Ge; a compound or alloy semiconductor including SiC, SiGe, GeSn, GaAs, GaP, GaAsP, AlInAs, AlGaAs, GaInAs, InAs, GaInP, InP, InSb, GaInAsP; a combination thereof, or the like. The substrate 500 may be doped or substantially un-doped. In some embodiments, the substrate 500 may be a sapphire substrate.

A dielectric layer 502 is formed over the substrate 500 by using suitable a deposition technique. In some embodiments, the dielectric layer 502 is formed by, for example, spin-on coating, chemical vapor deposition (CVD), plasma-enhanced CVD (PECVD), or the like. In some embodiments, the dielectric layer 502 is an interlayer dielectric (ILD) layer formed form silicon oxide (SiO₂), hafnium oxide (HfO₂), aluminum oxide (Al₂O₃), silicon nitride, amorphous boron nitride (a-BN), or the like. In some embodiments, the dielectric layer 502 has a thickness in a range from about 10 nm to about 1000 nm.

After the dielectric layer 502 is formed over the substrate 500, a plurality of carbon nanotubes (CNTs) 504 are formed over the dielectric layer 502. The CNTs 504 are arranged on the dielectric layer 502 and extend in substantially the same direction. In some embodiments, the CNTs 504 can be formed by various methods, such as arc-discharge or laser ablation methods, or a templated CVD method on a sapphire substrate. The formed CNTs 504 can be dispersed in a solvent, such as sodium dodecyl sulfate (SDS). The CNTs 504 can be transferred to and disposed on the dielectric layer 502 using various methods, such as a floating evaporative self-assembly method in some embodiments. For example, the CNTs 504 are first disposed on a dummy substrate, followed by forming a transfer film over the CNTs 504 and the dummy substrate, followed by detaching the transfer film from the dummy substrate together with the CNTs 504, followed by attaching the transfer film to the dielectric layer 502, and followed by detaching the transfer film from the dielectric layer 502, thereby leaving the CNTs 504 on the dielectric layer 502.

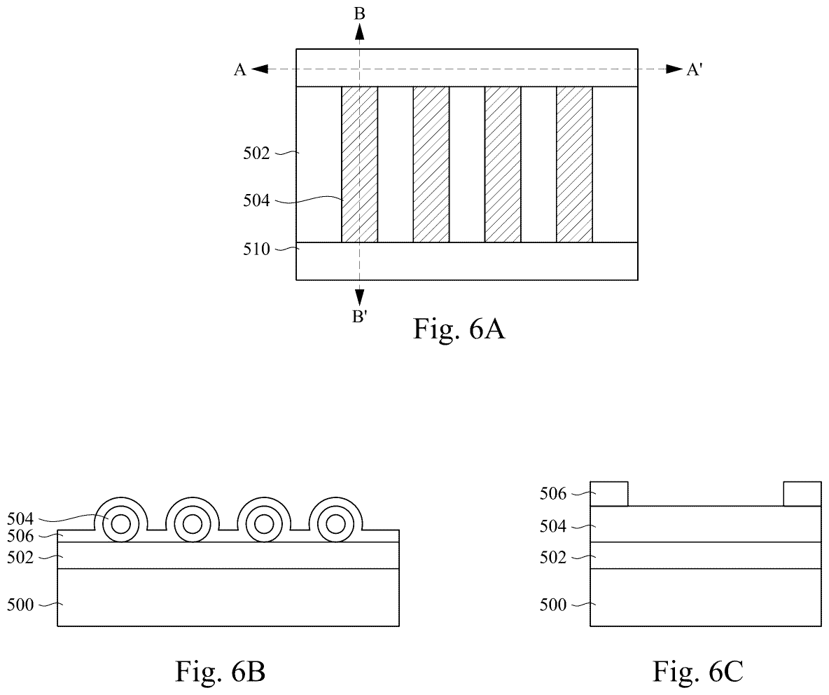

FIG. 6A is a top view of an intermediate stage in manufacturing of a CNTFET subsequent to the stage shown in FIGS. 5A-5C, FIG. 6B is a cross-sectional view obtained from cut A-A′ in FIG. 6A, and FIG. 6C is a cross-sectional view obtained from cut B-B′ in FIG. 6A. In FIGS. 6A-6C, source/drain contacts 506 are respective formed on source/drain regions of each CNT 504. From a top view as illustrated in FIG. 6A, each source/drain contact 506 has an elongated pattern extending along a direction perpendicular to the lengthwise direction of the CNTs 504 to across CNTs 504. In this way, source regions of the CNTs 504 share a continuous contact 506, and drain regions of the CNTs 504 share another continuous contact 506. In some embodiments, the source/drain contacts 506 include Pd, Pt, Au, Sc, Y, W, Ti, TiN, the like, or combinations thereof, and are formed by a suitable deposition technique, such as CVD, ALD, PVD, the like, or combinations thereof. In some embodiments, the source/drain contacts 506 each have a thickness in a range from about 20 nm to about 1000 nm.

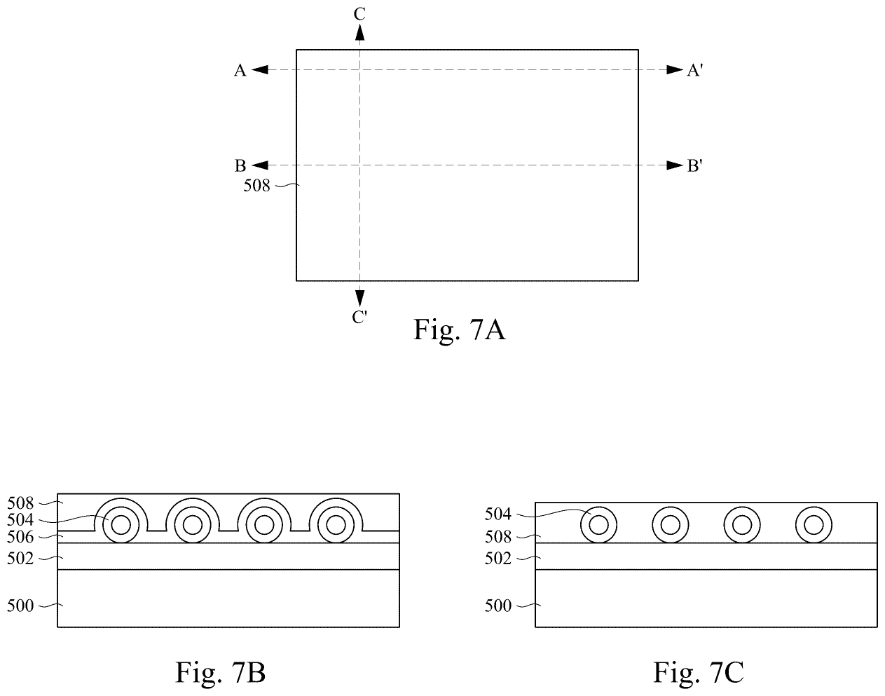

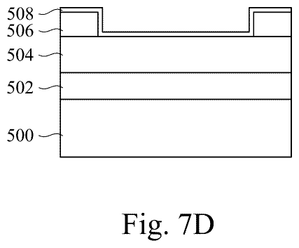

FIG. 7A is a top view of an intermediate stage in manufacturing of a CNTFET subsequent to the stage shown in FIGS. 6A-6C, FIG. 7B is a cross-sectional view obtained from cut A-A′ in FIG. 7A, FIG. 7C is a cross-sectional view obtained from cut B-B′ in FIG. 7A, and FIG. 7D is a cross-sectional view obtained from cut C-C′ in FIG. 7A. In FIGS. 7A-7D, a gate dielectric layer 508 is deposited over the source/drain contacts 506 and a channel region of each CNT 104. In some embodiments, the gate dielectric layer 508 may include an oxide-based dielectric or a nitride-based dielectric formed using a suitable deposition method, such as CVD, PVD, ALD, the like, or combinations thereof. For example, the gate dielectric layer 508 includes SiOₓ, HfOₓ, AlOₓ, YOₓ, ScOₓ, MoOₓ, WOₓ, VOₓ, SiNₓ, HfNₓ, AlNₓ, YNₓ, ScNₓ, the like, or combinations thereof. In some embodiments, the gate dielectric layer 508 has a thickness in a range from about 2 nm to about 100 nm. In some embodiments, as depicted in FIG. 7D, the gate dielectric layer 508 is formed through a conformal deposition process. This method ensures that the layer conforms to the underlying surface contours, which include the source/drain contacts 506 and the CNTs 504. It is noted that the gate dielectric layer 508 is not shown with a conformal profile in FIGS. 7B and 7C for simplicity of illustration, and to illustrate that the diameters of the CNTs 504 are significantly smaller than the thickness of the gate dielectric layer 508.

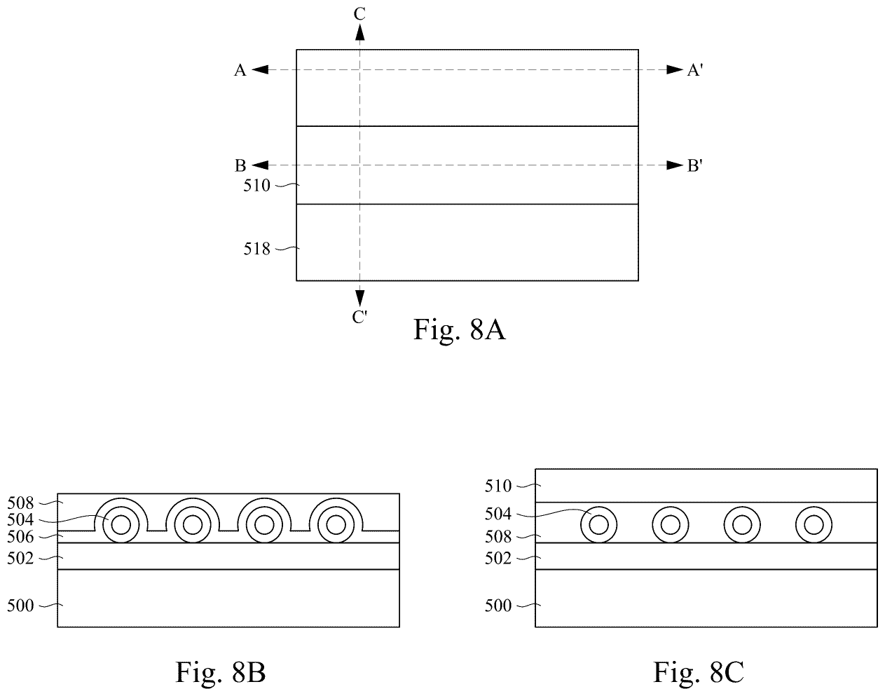

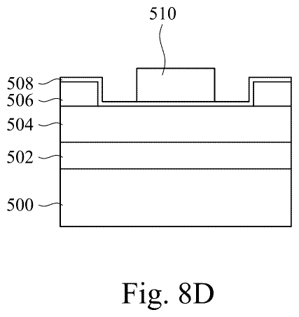

FIG. 8A is a top view of an intermediate stage in manufacturing of a CNTFET subsequent to the stage shown in FIGS. 7A-7D, FIG. 8B is a cross-sectional view obtained from cut A-A′ in FIG. 8A, FIG. 8C is a cross-sectional view obtained from cut B-B′ in FIG. 8A, and FIG. 8D is a cross-sectional view obtained from cut C-C′ in FIG. 8A. In FIGS. 8A-8D, a gate electrode 510 is formed over a portion of the gate dielectric layer 508 that is localized to channel regions of the CNTs 504, by using suitable deposition and patterning techniques. For example, in the process of forming the gate electrode 510, various deposition techniques can be employed to deposit one or more metal layers over the gate dielectric layer 508. For example, the one or more metal layers can be deposited over the gate dielectric layer 508 by using, for example, PVD, CVD, plasma-enhanced CVD (PECVD), or the like. Once the metal layer(s) of the gate electrode 510 are deposited, the next step involves patterning them to form the gate electrode 510. This can be achieved through photolithography, a process that involves coating the one ore more metal layers with a photoresist which is light-sensitive material. In some embodiments, the photoresist is then exposed to ultraviolet light through a photomask, which bears the target pattern of the gate electrode 510. In some embodiments, the exposed areas of the photoresist become soluble and are developed away, revealing the underlying metal. An etching process is then employed to remove the unprotected metal, leaving behind the patterned gate electrode 510. The etching can be done using wet chemical etchants or by dry etching techniques such as reactive ion etching (RIE), which provides high anisotropy and fidelity to the original pattern.

In some embodiments, as illustrated in FIGS. 8A and 8C, the gate electrode 510 has an elongated pattern extending along a direction perpendicular to the lengthwise direction of the CNTs 504. In this way, channel regions of the CNTs 504 share a continuous gate electrode 510. In some other embodiments, the gate electrode 510 may be patterned into discontinuous gate electrodes respectively over the CNTs 504, and the channel regions of the CNTs 504 can be controlled by using respective gate electrodes. In some embodiments, the gate electrode 510 includes Pd, Pt, Au, Sc, Y, W, Ti, TiN, the like, or combinations thereof. In some embodiments, the gate electrode 510 has a thickness in a range from about 20 nm to about 1000 nm.

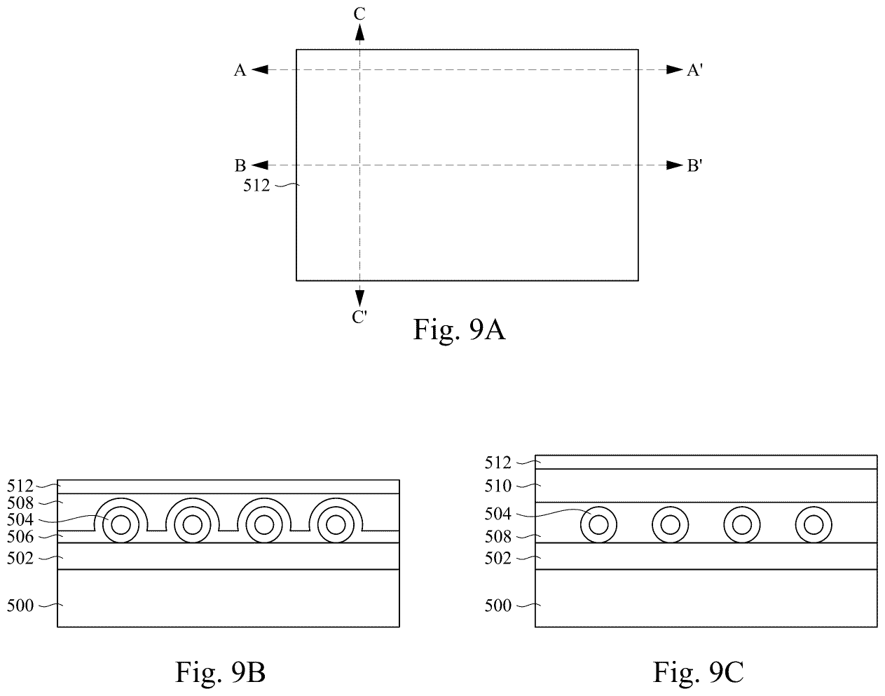

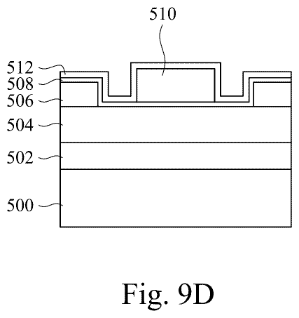

FIG. 9A is a top view of an intermediate stage in manufacturing of a CNTFET subsequent to the stage shown in FIGS. 8A-8D, FIG. 9B is a cross-sectional view obtained from cut A-A′ in FIG. 9A, FIG. 9C is a cross-sectional view obtained from cut B-B′ in FIG. 9A, and FIG. 9D is a cross-sectional view obtained from cut C-C′ in FIG. 9A. In FIGS. 9A-9D, an oxide-based dielectric layer 512 is formed over the source/drain contacts 506 and the gate electrode 510. The oxide-based dielectric layer 512 serves to enhance the electrostatic doping effect and improve the carrier mobility in the source/drain regions in the CNTs 504. In some embodiments, the oxide-based dielectric layer 512 is a non-stoichiometric oxide layer with oxygen vacancies. For example, the oxide-based dielectric layer 512 may include non-stoichiometric SiOₓ, HfOₓ, AlOₓ, YOₓ, ScOₓ, MoOₓ, WOₓ, VOₓ, or the like.

In some embodiments where the oxide-based dielectric layer 512 is non-stoichiometric metal oxide (e.g., non-stoichiometric yttrium oxide), it can be formed by firstly depositing a metal layer (e.g., an yttrium layer) blanket over the gate dielectric layer 508 and the gate electrode 510, followed by oxidizing the metal layer into non-stoichiometric metal oxide. The process of forming the non-stoichiometric yttrium oxide (YOₓ) involves control over the oxidation environment to create a desired level or concentration of oxygen vacancies within the oxide-based layer 512. By adjusting parameters such as the temperature, pressure, and the oxidizing agent's flow rate during the oxidation process, a tailored non-stoichiometric yttrium oxide layer with desired level or concentration of oxygen vacancies can be achieved. In some embodiments, the oxide-based dielectric layer 512 has a thickness smaller than a thickness than a minimal thickness of the gate dielectric layer 508 and a minimal thickness of the gate electrode 510.

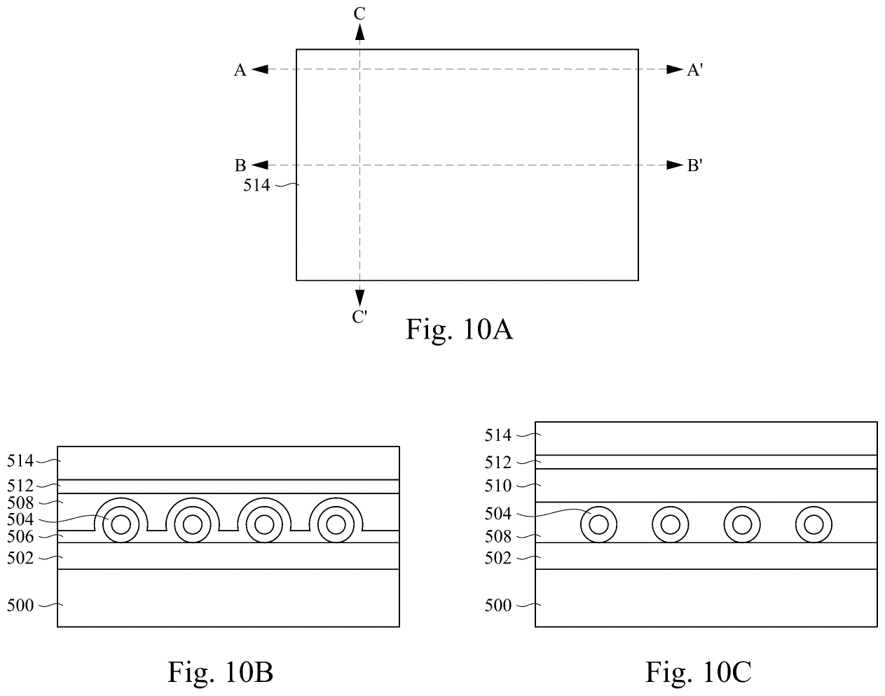

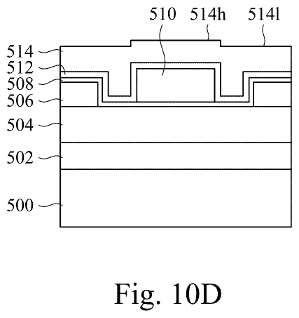

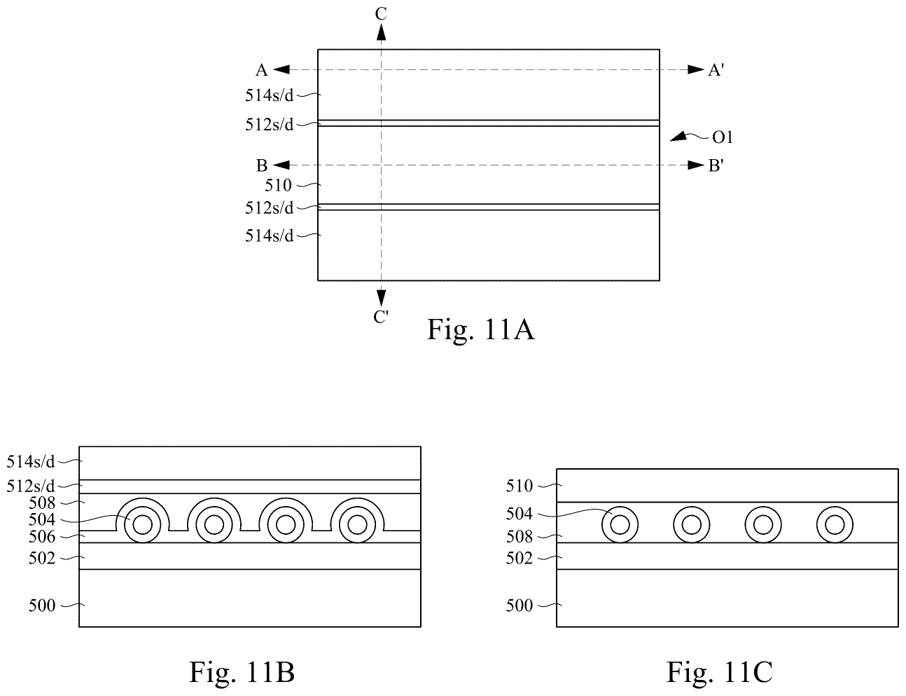

FIG. 10A is a top view of an intermediate stage in manufacturing of a CNTFET subsequent to the stage shown in FIGS. 9A-9D, FIG. 10B is a cross-sectional view obtained from cut A-A′ in FIG. 10A, FIG. 10C is a cross-sectional view obtained from cut B-B′ in FIG. 10A, and FIG. 10D is a cross-sectional view obtained from cut C-C′ in FIG. 10A. In FIGS. 10A-10D, a nitride-based dielectric layer 514 is formed over the oxide-based dielectric layer 512. The nitride-based dielectric layer 514 is formed of non-stoichiometric nitride with nitrogen vacancies, thereby serving to induce an electrostatic doping effect on source/drain regions of the CNTs 504, as discussed in detailed with respect to the experimental results shown in FIGS. 3B, 3C and 4C. In some embodiments, the nitride-based dielectric layer 514 include SiNₓ, HfNₓ, AlNₓ, YNₓ, ScNₓ, the like or combinations thereof.

In some embodiments, the nitride-based dielectric layer 514 includes non-stoichiometric aluminum nitride where the atomic ratio of aluminum (Al) to nitrogen (N) deviates from the stoichiometric ratio of 1:1 to create desired level or concentration of nitrogen vacancies within the nitride-based dielectric layer 514. The precise control of material composition at the atomic level to create desired level of nitrogen vacancies can be achieved by using, for example, an atomic layer deposition (ALD) process. The ALD process involves the sequential use of gas phase chemical processes. The oxide-based dielectric layer 512 is exposed to alternating precursor gases that do not overlap but instead react with the surface in a sequential manner, allowing for the atomic layer-by-layer growth of the film. To create non-stoichiometric aluminum nitride with nitrogen vacancies, the ALD process involves the use of an aluminum-containing precursor, such as trimethylaluminum (TMA), and a nitrogen-containing precursor, such as ammonia (NH₃). By adjusting the exposure time to the nitrogen-containing precursor and the purge times between the aluminum-containing precursor pulses, the atomic ratio of aluminum to nitrogen can be manipulated. For instance, a shorter exposure time to the nitrogen-containing precursor or a longer purge time after the nitrogen-containing precursor can lead to a lower concentration of nitrogen, thereby creating nitrogen vacancies within the nitride-based dielectric layer 514. The process temperature and pressure can be also adjusted to control the stoichiometry of the non-stoichiometric AlN film to obtain a desired level of nitrogen vacancies.

As illustrated in FIG. 10D, in some embodiments, the nitride-based dielectric layer 514 has a top surface with a higher region 514h overlapping with the channel region of the CNT 504 and lower regions 514l overlapping with the source/drain regions of the CNT 504. This is due to the gate electrode 510 having a top surface higher than top surfaces of the source/drain contacts 506. In some embodiments, the nitride-based dielectric layer 514 has a minimal thickness greater than a maximal thickness of the oxide-based dielectric layer 512, which allows for forming a sufficient thick nitride-based dielectric layer 514 at a sufficient short distance from the CNT 504, thereby improving the electrostatic doping effect.

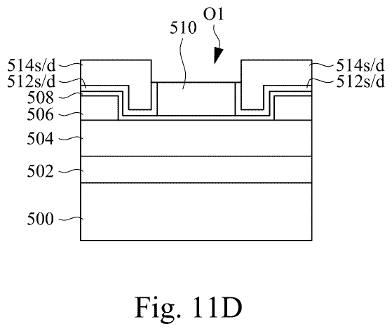

FIG. 11A is a top view of an intermediate stage in manufacturing of a CNTFET subsequent to the stage shown in FIGS. 10A-10D, FIG. 11B is a cross-sectional view obtained from cut A-A′ in FIG. 11A, FIG. 11C is a cross-sectional view obtained from cut B-B′ in FIG. 11A, and FIG. 11D is a cross-sectional view obtained from cut C-C′ in FIG. 11A. In FIGS. 11A-11D, the nitride-based dielectric layer 514 and the oxide-based dielectric layer 512 are patterned to form a trench O1 that exposes a top surface of the gate electrode 510 by using suitable photolithography and etching techniques. For example, a photoresist layer is formed over the nitride-based dielectric layer 514 by using a spin-on coating process, followed by patterning the photoresist layer to expose target regions of the nitride-based dielectric layer 514 using suitable photolithography techniques. For example, photoresist layer is irradiated (exposed) and developed to remove portions of the photoresist layer. In greater detail, a photomask or reticle (not shown) may be placed above the photoresist layer, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist layer, and a developer may be used to remove either the exposed or unexposed portions of the photoresist material depending on whether a positive or negative resist is used. After the patterned photoresist layer is formed, one or more etching processes are performed on a region of the nitride-based dielectric layer 514 and the oxide-based dielectric layer 512 corresponding to the pattern of gate electrode 510, thereby forming a trench O1 in the nitride-based dielectric layer 514 and the oxide-based dielectric layer 512.

In some embodiments, the trench O1 is etched in the nitride-based dielectric layer 514 by using a selective etching process that selectively etches the nitride-based dielectric layer 514 with no or negligible etch amount in the oxide-based dielectric layer 512. For example, the nitride-based dielectric layer 514 can be selectively etched by using phosphoric acid. After the initial etching of the trench O1 in the nitride-based dielectric layer 514, the trench O1 is then etched in the oxide-based dielectric layer 512 by using another selective etching process that selectively etches the oxide-based dielectric layer 512 with no or negligible etch amount in the gate electrode 510. For example, the oxide-based dielectric layer 512 can be selectively etched by using hydrofluoric acid (HF). The selective etching of oxide-based dielectric layer 512 continues until the top surface of the gate electrode 510 gets exposed.

As illustrated in FIGS. 11A and 11D, the trench O1 extends in parallel with the gate electrode 510 and breaks the continuous nitride-based dielectric layer 514 into two separate nitride-based dielectric layers 514s/d spaced apart by the gate electrode 510. The trench O1 further breaks the continuous oxide-based dielectric layer 512 into separate oxide-based dielectric layers 512s/d spaced apart by the gate electrode 510. Each nitride-based dielectric layer 514s/d and an underlying oxide-based dielectric layer 512s/d collectively overlap a source/drain region within the CNT 504, inducing n-type carriers (i.e., electrons) in the source/drain region within the CNT 504 by using the electrostatic doping effect.

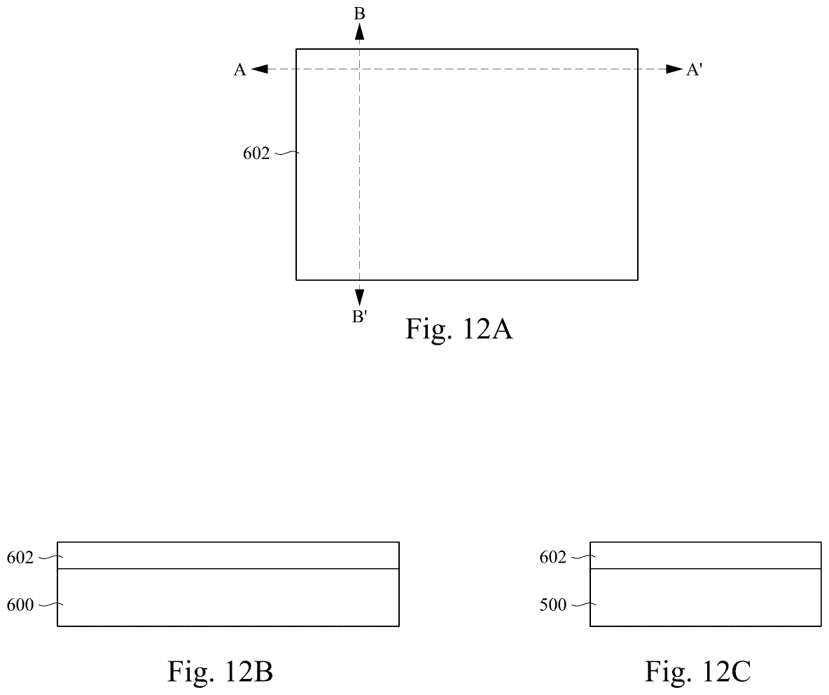

FIGS. 12A-18D illustrate top views and cross-sectional views of intermediate stages in formation of an example CNTFET in accordance with some embodiments of the present disclosure. Although the top views and cross-sectional views shown in FIGS. 12A-18D are described with reference to a method, it will be appreciated that the structures shown in FIGS. 12A-18D are not limited to the method but rather may stand alone separate of the method. Although FIGS. 12A-18D are described as a series of acts, it will be appreciated that these acts are not limiting in that the order of the acts can be altered in other embodiments, and the methods disclosed are also applicable to other structures.

FIG. 12A is a top view of an intermediate stage in manufacturing of a CNTFET, FIG. 12B is a cross-sectional view obtained from cut A-A′ in FIG. 12A, and FIG. 12C is a cross-sectional view obtained from cut B-B′ in FIG. 12A. In FIGS. 12A-12C, a dielectric layer 602 is formed over the substrate 600. The dielectric layer 602 and the substrate 600 can be respectively the same as the dielectric layer 502 and the substrate 500, and thus details of the dielectric layer 602 and the substrate 600 are not repeated for the sake of brevity.

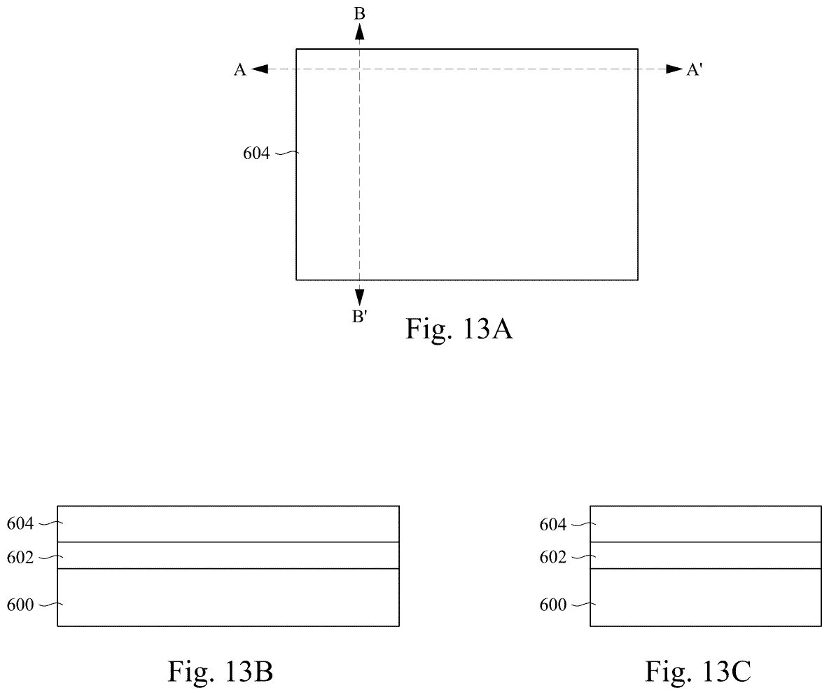

FIG. 13A is a top view of an intermediate stage in manufacturing of a CNTFET subsequent to the stage shown in FIGS. 12A-12C, FIG. 13B is a cross-sectional view obtained from cut A-A′ in FIG. 13A, and FIG. 13C is a cross-sectional view obtained from cut B-B′ in FIG. 13A. In FIGS. 13A-13C, a nitride-based dielectric layer 604 is formed over the dielectric layer 602. The nitride-based dielectric layer 604 is formed of non-stoichiometric nitride with nitrogen vacancies, thereby serving to induce an electrostatic doping effect on source/drain regions of subsequently formed CNTs, as discussed in detailed with respect to the experimental results shown in FIGS. 3B, 3C and 4C. In some embodiments, the nitride-based dielectric layer 604 include SiNₓ, HfNₓ, AlNₓ, YNₓ, ScNₓ, the like or combinations thereof.

In some embodiments, the nitride-based dielectric layer 604 includes non-stoichiometric aluminum nitride where the atomic ratio of aluminum (Al) to nitrogen (N) deviates from the stoichiometric ratio of 1:1 to create desired level or concentration of nitrogen vacancies within the nitride-based dielectric layer 604. The precise control of material composition at the atomic level to create desired level of nitrogen vacancies can be achieved by using, for example, an atomic layer deposition (ALD) process. The ALD process involves the sequential use of gas phase chemical processes. The dielectric layer 602 is exposed to alternating precursor gases that do not overlap but instead react with the surface in a sequential manner, allowing for the atomic layer-by-layer growth of the film. To create non-stoichiometric aluminum nitride with nitrogen vacancies, the ALD process involves the use of an aluminum-containing precursor, such as trimethylaluminum (TMA), and a nitrogen-containing precursor, such as ammonia (NH₃). By adjusting the exposure time to the nitrogen-containing precursor and the purge times between the aluminum-containing precursor pulses, the atomic ratio of aluminum to nitrogen can be manipulated. For instance, a shorter exposure time to the nitrogen-containing precursor or a longer purge time after the nitrogen-containing precursor can lead to a lower concentration of nitrogen, thereby creating nitrogen vacancies within the nitride-based dielectric layer 604. The process temperature and pressure can be also adjusted to control the stoichiometry of the non-stoichiometric AIN film to obtain a desired level of nitrogen vacancies.

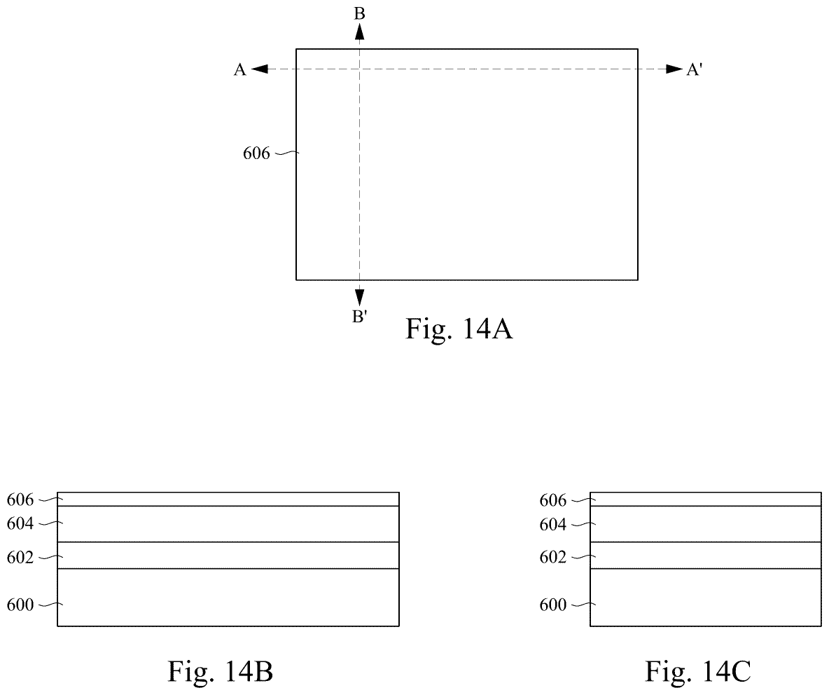

FIG. 14A is a top view of an intermediate stage in manufacturing of a CNTFET subsequent to the stage shown in FIGS. 13A-13C, FIG. 14B is a cross-sectional view obtained from cut A-A′ in FIG. 14A, and FIG. 14C is a cross-sectional view obtained from cut B-B′ in FIG. 14A. In FIGS. 14A-14C, an oxide-based dielectric layer 606 is formed over the nitride-based dielectric layer 604. The oxide-based dielectric layer 606 serves to enhance the electrostatic doping effect and improve the carrier mobility in the source/drain regions in the subsequently formed CNTs. In some embodiments, the oxide-based dielectric layer 606 is a non-stoichiometric oxide layer with oxygen vacancies. For example, the oxide-based dielectric layer 606 may include non-stoichiometric SiOₓ, HfOₓ, AlOₓ, YOₓ, ScOₓ, MoOₓ, WOₓ, VOₓ, or the like.

In some embodiments where the oxide-based dielectric layer 606 is non-stoichiometric metal oxide (e.g., non-stoichiometric yttrium oxide), it can be formed by firstly depositing a metal layer (e.g., an yttrium layer) blanket over the nitride-based dielectric layer 604, followed by oxidizing the metal layer into non-stoichiometric metal oxide. The process of forming the non-stoichiometric yttrium oxide (YOₓ) involves control over the oxidation environment to create a desired level or concentration of oxygen vacancies within the oxide-based dielectric layer 606. By adjusting parameters such as the temperature, pressure, and the oxidizing agent's flow rate during the oxidation process, a tailored non-stoichiometric yttrium oxide layer with desired level or concentration of oxygen vacancies can be achieved. In some embodiments, the oxide-based dielectric layer 606 has a thickness less than a thickness of the nitride-based dielectric layer 604, which allows for forming a sufficient thick nitride-based dielectric layer 606 at a sufficient short distance from the subsequently formed CNT, thereby improving the electrostatic doping effect.

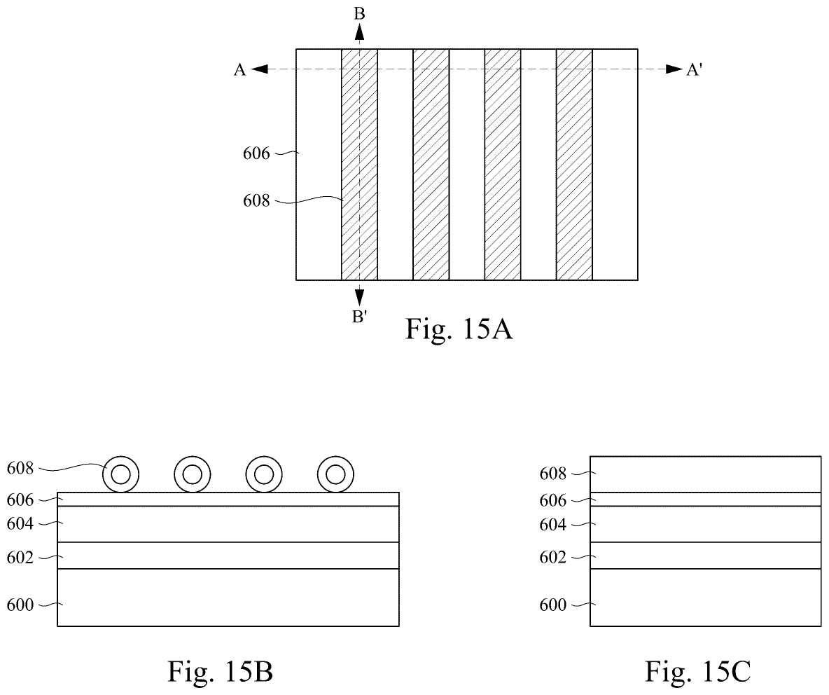

FIG. 15A is a top view of an intermediate stage in manufacturing of a CNTFET subsequent to the stage shown in FIGS. 14A-14C, FIG. 15B is a cross-sectional view obtained from cut A-A′ in FIG. 15A, and FIG. 15C is a cross-sectional view obtained from cut B-B′ in FIG. 15A. In FIGS. 15A-15C, a plurality of carbon nanotubes (CNTs) 608 are formed over the oxide-based dielectric layer 606. The CNTs 608 are arranged on the oxide-based dielectric layer 606 and extend in substantially the same direction. In some embodiments, the CNTs 608 can be formed by various methods, such as arc-discharge or laser ablation methods, or a templated CVD method on a sapphire substrate. The formed CNTs 608 can be dispersed in a solvent, such as sodium dodecyl sulfate (SDS). The CNTs 608 can be transferred to and disposed on the oxide-based dielectric layer 606 using various methods, such as a floating evaporative self-assembly method in some embodiments. For example, the CNTs 608 are first disposed on a dummy substrate, followed by forming a transfer film over the CNTs 608 and the dummy substrate, followed by detaching the transfer film from the dummy substrate together with the CNTs 608, followed by attaching the transfer film to the oxide-based dielectric layer 606, and followed by detaching the transfer film from the oxide-based dielectric layer 606, thereby leaving the CNTs 608 on the oxide-based dielectric layer 606.

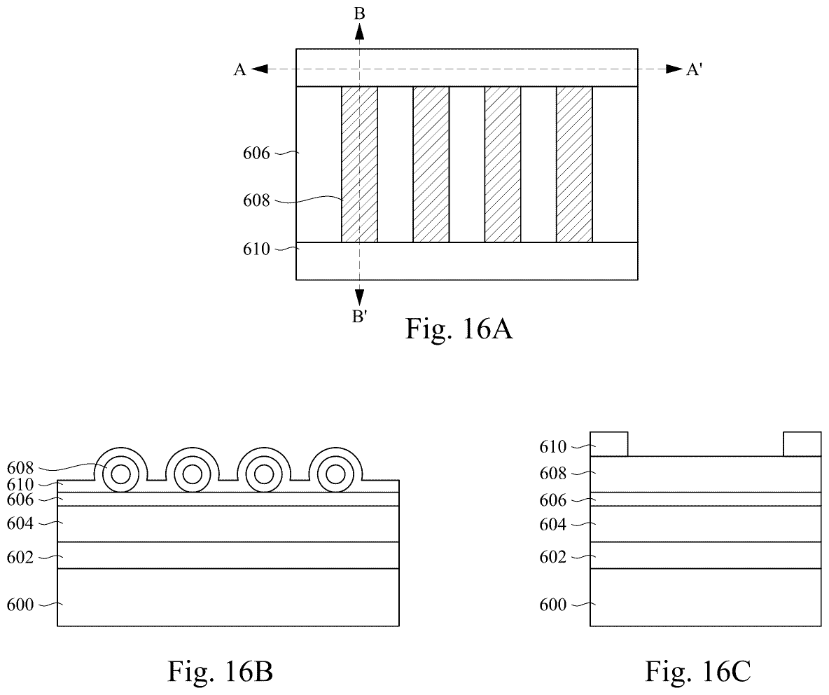

FIG. 16A is a top view of an intermediate stage in manufacturing of a CNTFET subsequent to the stage shown in FIGS. 15A-15C, FIG. 16B is a cross-sectional view obtained from cut A-A′ in FIG. 16A, and FIG. 16C is a cross-sectional view obtained from cut B-B′ in FIG. 16A. In FIGS. 16A-16C, source/drain contacts 610 are respective formed on source/drain regions of each CNT 608. From a top view as illustrated in FIG. 6A, each source/drain contact 610 has an elongated pattern extending along a direction perpendicular to the lengthwise direction of the CNTs 608 to across CNTs 608. In this way, source regions of the CNTs 608 share a continuous contact 610, and drain regions of the CNTs 608 share another continuous contact 610. In some embodiments, the source/drain contacts 610 include Pd, Pt, Au, Sc, Y, W, Ti, TiN, the like, or combinations thereof, and are formed by a suitable deposition technique, such as CVD, ALD, PVD, the like, or combinations thereof. As illustrated in FIG. 16B, the source/drain contacts 610 have a bottom surface in contact with a top surface of the oxide-based dielectric layer 606.

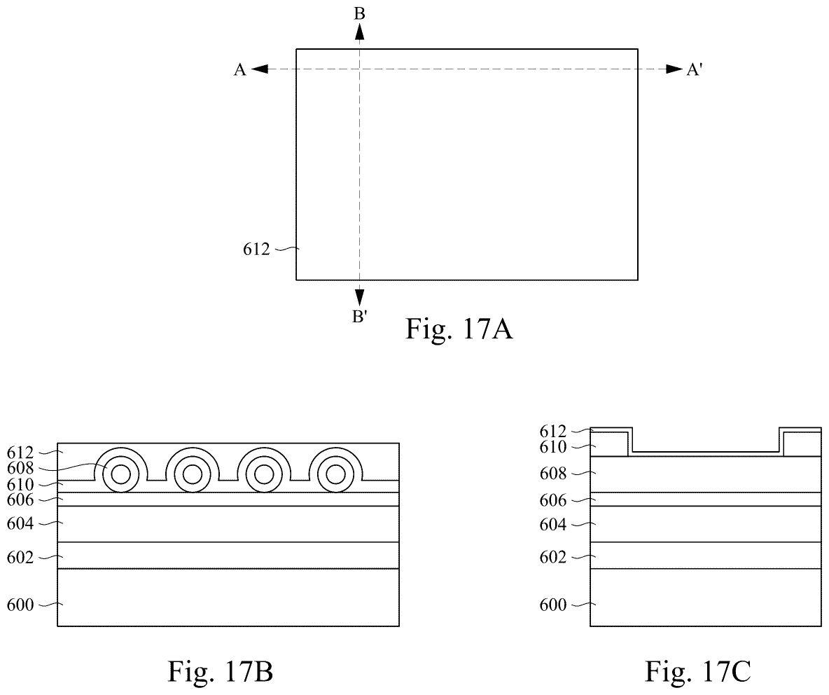

FIG. 17A is a top view of an intermediate stage in manufacturing of a CNTFET subsequent to the stage shown in FIGS. 16A-16C, FIG. 17B is a cross-sectional view obtained from cut A-A′ in FIG. 17A, and FIG. 17C is a cross-sectional view obtained from cut B-B′ in FIG. 17A. In FIGS. 17A-17C, a gate dielectric layer 612 is deposited over the source/drain contacts 506 and a channel region of each CNT 608. In some embodiments, the gate dielectric layer 612 may include an oxide-based dielectric or a nitride-based dielectric formed using a suitable deposition method, such as CVD, PVD, ALD, the like, or combinations thereof. For example, the gate dielectric layer 612 includes SiOₓ, HfOₓ, AlOₓ, YOₓ, ScOₓ, MoOₓ, WOₓ, VOₓ, SiNₓ, HfNₓ, AlNₓ, YNₓ, ScNₓ, the like, or combinations thereof. In some embodiments, the gate dielectric layer 612 has a thickness in a range from about 2 nm to about 100 nm. In some embodiments, as depicted in FIG. 17C, the gate dielectric layer 612 is formed through a conformal deposition process. This method ensures that the layer conforms to the underlying surface contours, which include the source/drain contacts 610 and the CNTs 608. It is noted that the gate dielectric layer 612 is not shown with a conformal profile in FIG. 17B for simplicity of illustration, and to illustrate that the diameters of the CNTs 608 are significantly smaller than the thickness of the gate dielectric layer 612.

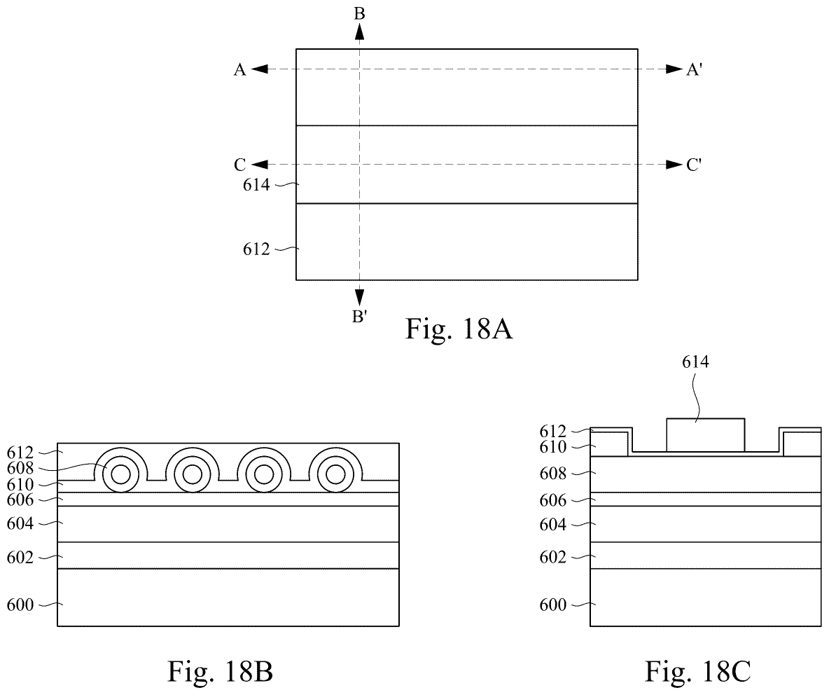

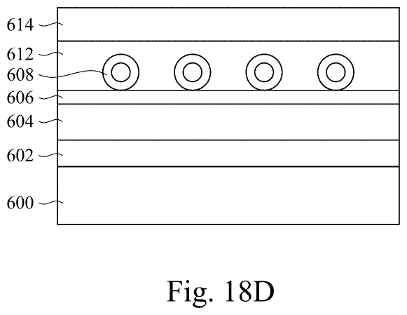

FIG. 18A is a top view of an intermediate stage in manufacturing of a CNTFET subsequent to the stage shown in FIGS. 17A-17C, FIG. 18B is a cross-sectional view obtained from cut A-A′ in FIG. 18A, FIG. 18C is a cross-sectional view obtained from cut B-B′ in FIG. 18A, and FIG. 18D is a cross-sectional view obtained from cut C-C′ in FIG. 18A. In FIGS. 18A-18D, a gate electrode 614 is formed over a portion of the gate dielectric layer 612 that is localized to channel regions of the CNTs 608, by using suitable deposition and patterning techniques. In some embodiments, the gate electrode 614 has an elongated pattern extending along a direction perpendicular to the lengthwise direction of the CNTs 608. In this way, channel regions of the CNTs 608 share a continuous gate electrode 614. In some other embodiments, the gate electrode 614 may be patterned into discontinuous gate electrodes respectively over the CNTs 608, and the channel regions of the CNTs 608 can be controlled by using respective gate electrodes. In some embodiments, the gate electrode 614 includes Pd, Pt, Au, Sc, Y, W, Ti, TiN, the like, or combinations thereof.

In the CNTFET device as shown in FIGS. 18A-18D, the nitride-based dielectric layer 604 and oxide-based dielectric layer 606 overlap an entirety of the CNT 608, and thus may induce electrostatic doping effect on the entirety of the CNT 608. In such scenario, the CNTFET's operation voltage may be different from that of the CNTFET as illustrated in FIGS. 11A-11D.

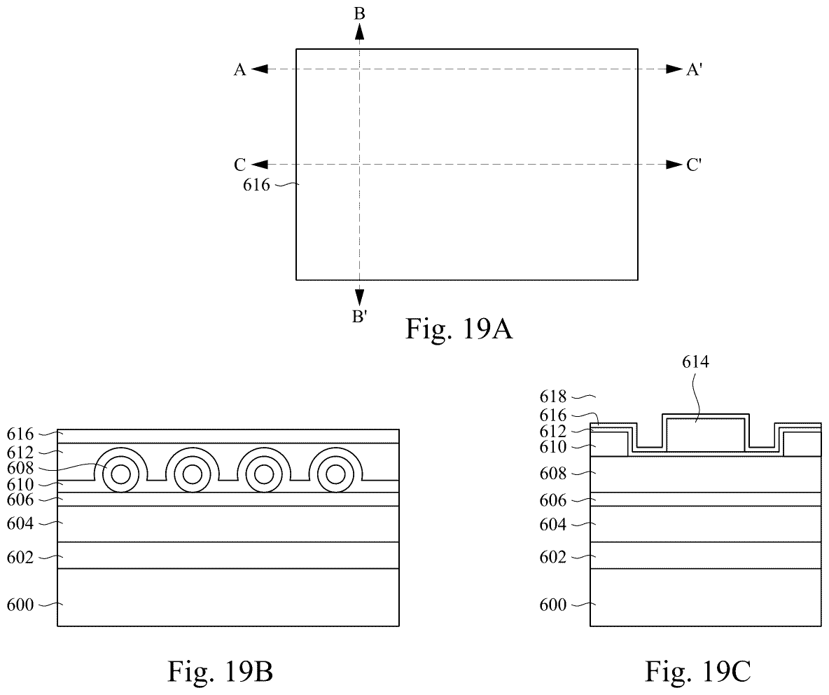

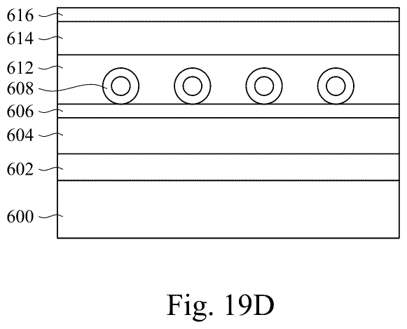

FIGS. 19A-21D illustrate top views and cross-sectional views of intermediate stages in formation of an example CNTFET in accordance with some embodiments of the present disclosure. Although the top views and cross-sectional views shown in FIGS. 19A-21D are described with reference to a method, it will be appreciated that the structures shown in FIGS. 19A-21D are not limited to the method but rather may stand alone separate of the method. Although FIGS. 19A-21D are described as a series of acts, it will be appreciated that these acts are not limiting in that the order of the acts can be altered in other embodiments, and the methods disclosed are also applicable to other structures.

FIG. 19A is a top view of an intermediate stage in manufacturing of a CNTFET, FIG. 19B is a cross-sectional view obtained from cut A-A′ in FIG. 19A, FIG. 19C is a cross-sectional view obtained from cut B-B′ in FIG. 19A, and FIG. 19D is a cross-sectional view obtained from cut C-C′ in FIG. 19A. The CNTFET illustrated in FIGS. 19A-19D is generally the same as that illustrated in FIGS. 18A-18D, except that an additional oxide-based dielectric layer 616 is formed over the gate dielectric layer 612 and the gate electrode 614. The oxide-based dielectric layer 616 serves to enhance the electrostatic doping effect and improve the carrier mobility in the source/drain regions in the CNTs 608. In some embodiments, the oxide-based dielectric layer 616 is a non-stoichiometric oxide layer with oxygen vacancies. For example, the oxide-based dielectric layer 616 may include non-stoichiometric SiOₓ, HfOₓ, AlOₓ, YOₓ, ScOₓ, MoOₓ, WOₓ, VOₓ, or the like.

In some embodiments where the oxide-based dielectric layer 616 is non-stoichiometric metal oxide (e.g., non-stoichiometric yttrium oxide), it can be formed by firstly depositing a metal layer (e.g., an yttrium layer) blanket over the gate dielectric layer 612 and the gate electrode 614, followed by oxidizing the metal layer into non-stoichiometric metal oxide. The process of forming the non-stoichiometric yttrium oxide (YOₓ) involves control over the oxidation environment to create a desired level or concentration of oxygen vacancies within the oxide-based dielectric layer 616. By adjusting parameters such as the temperature, pressure, and the oxidizing agent's flow rate during the oxidation process, a tailored non-stoichiometric yttrium oxide layer with desired level or concentration of oxygen vacancies can be achieved.

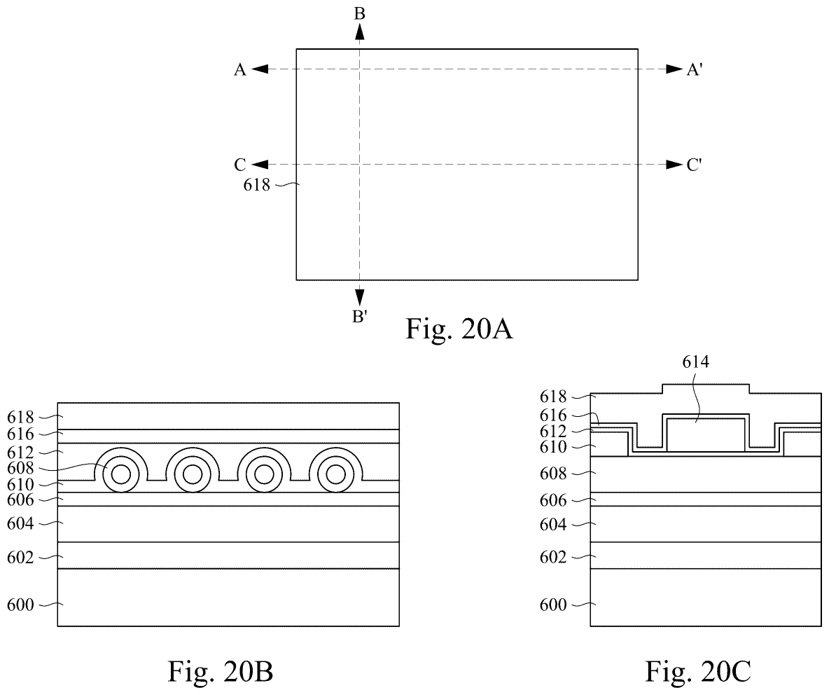

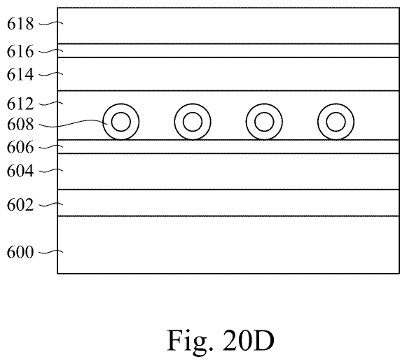

FIG. 20A is a top view of an intermediate stage in manufacturing of a CNTFET subsequent to the stage shown in FIGS. 19A-19D, FIG. 20B is a cross-sectional view obtained from cut A-A′ in FIG. 20A, FIG. 20C is a cross-sectional view obtained from cut B-B′ in FIG. 20A, and FIG. 20D is a cross-sectional view obtained from cut C-C′ in FIG. 20A. In FIGS. 20A-20D, a nitride-based dielectric layer 618 is formed over the oxide-based dielectric layer 616. The nitride-based dielectric layer 618 is formed of non-stoichiometric nitride with nitrogen vacancies, thereby serving to induce an electrostatic doping effect on source/drain regions of subsequently formed CNTs, as discussed in detailed with respect to the experimental results shown in FIGS. 3B, 3C and 4C. In some embodiments, the nitride-based dielectric layer 618 include SiNₓ, HfNₓ, AlNₓ, YNₓ, ScNₓ, the like or combinations thereof.

In some embodiments, the nitride-based dielectric layer 618 includes non-stoichiometric aluminum nitride where the atomic ratio of aluminum (Al) to nitrogen (N) deviates from the stoichiometric ratio of 1:1 to create desired level or concentration of nitrogen vacancies within the nitride-based dielectric layer 618. The precise control of material composition at the atomic level to create desired level of nitrogen vacancies can be achieved by using, for example, an atomic layer deposition (ALD) process. The ALD process involves the sequential use of gas phase chemical processes. The oxide-based dielectric layer 616 is exposed to alternating precursor gases that do not overlap but instead react with the surface in a sequential manner, allowing for the atomic layer-by-layer growth of the film. To create non-stoichiometric aluminum nitride with nitrogen vacancies, the ALD process involves the use of an aluminum-containing precursor, such as trimethylaluminum (TMA), and a nitrogen-containing precursor, such as ammonia (NH₃). By adjusting the exposure time to the nitrogen-containing precursor and the purge times between the aluminum-containing precursor pulses, the atomic ratio of aluminum to nitrogen can be manipulated. For instance, a shorter exposure time to the nitrogen-containing precursor or a longer purge time after the nitrogen-containing precursor can lead to a lower concentration of nitrogen, thereby creating nitrogen vacancies within the nitride-based dielectric layer 618. The process temperature and pressure can be also adjusted to control the stoichiometry of the non-stoichiometric AlN film to obtain a desired level of nitrogen vacancies.

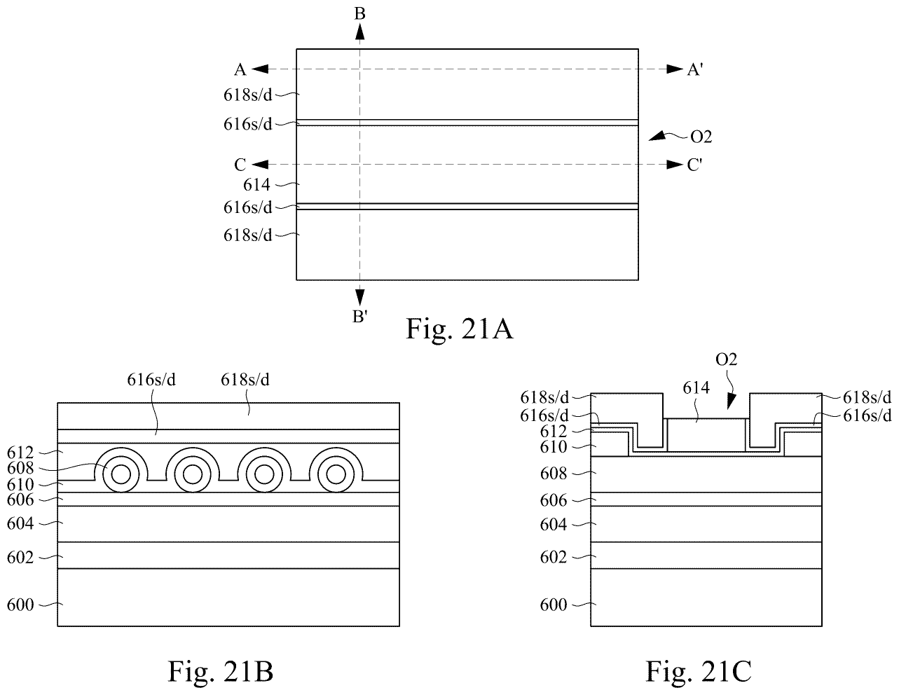

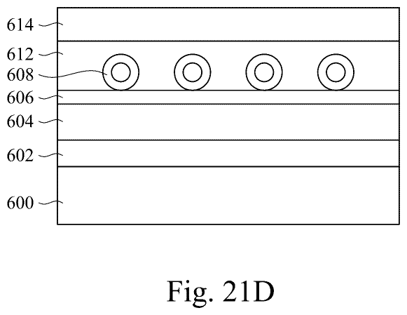

FIG. 21A is a top view of an intermediate stage in manufacturing of a CNTFET subsequent to the stage shown in FIGS. 20A-20D, FIG. 21B is a cross-sectional view obtained from cut A-A′ in FIG. 21A, FIG. 21C is a cross-sectional view obtained from cut B-B′ in FIG. 21A, and FIG. 21D is a cross-sectional view obtained from cut C-C′ in FIG. 21A. In FIGS. 21A-21D, the nitride-based dielectric layer 618 and the oxide-based dielectric layer 616 are patterned to form a trench O2 that exposes a top surface of the gate electrode 614 by using suitable photolithography and etching techniques.

In some embodiments, the trench O2 is etched in the nitride-based dielectric layer 618 by using a selective etching process that selectively etches the nitride-based dielectric layer 618 with no or negligible etch amount in the oxide-based dielectric layer 616. For example, the nitride-based dielectric layer 618 can be selectively etched by using phosphoric acid. After the initial etching of the trench O2 in the nitride-based dielectric layer 618, the trench O2 is then etched in the oxide-based dielectric layer 616 by using another selective etching process that selectively etches the oxide-based dielectric layer 616 with no or negligible etch amount in the gate electrode 614. For example, the oxide-based dielectric layer 616 can be selectively etched by using hydrofluoric acid (HF). The selective etching of oxide-based dielectric layer 616 continues until the top surface of the gate electrode 614 gets exposed.

As illustrated in FIGS. 21A and 21C, the trench O2 extends in parallel with the gate electrode 614 and breaks the continuous nitride-based dielectric layer 618 into two separate nitride-based dielectric layers 618s/d spaced apart by the gate electrode 614. The trench O2 further breaks the continuous oxide-based dielectric layer 616 into separate oxide-based dielectric layers 616s/d spaced apart by the gate electrode 614. Each nitride-based dielectric layer 618s/d and an underlying oxide-based dielectric layer 616s/d collectively overlap a source/drain region within the CNT 504, inducing n-type carriers (i.e., electrons) in the source/drain region within the CNT 504 by using the electrostatic doping effect.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that source/drain regions of the CNTFET can be doped by using an electrostatic doping effect without implanting dopant species into the CNTs, which in turn prevents potential damages caused by performing ion implantation on the CNTs.

In some embodiments, the present disclosure provides a method that includes the steps of disposing a plurality of nanostructures over a substrate and forming a first source/drain contact over the first source/drain regions of the plurality of nanostructures. Additionally, the method involves forming a second source/drain contact over the second source/drain regions of the plurality of nanostructures and forming a gate electrode over the channel regions of the plurality of nanostructures. Furthermore, the method includes forming a solid-state doping layer over the gate electrode, as well as over the first and second source/drain contacts. The method concludes with removing a first portion of the solid-state doping layer from the top surface of the gate electrode, while a second portion and a third portion of the solid-state doping layer are left over the first and second source/drain contacts, respectively. In some embodiments, the method further includes forming an oxygen-vacancy-containing oxide layer over the first and second source/drain contacts. In some embodiments, the oxygen-vacancy-containing oxide layer is formed prior to forming the solid-state doping layer. In some embodiments, the oxygen-vacancy-containing oxide layer has a thickness less than a minimal thickness of the solid-state doping layer. The oxygen-vacancy-containing oxide layer is further formed over the gate electrode. The method further includes removing a first portion of the oxygen-vacancy-containing oxide layer from the top surface of the gate electrode, while leaving a second portion and a third portion of the oxygen-vacancy-containing oxide layer over the first and second contacts, respectively. In some embodiments, the oxygen-vacancy-containing oxide layer comprises SiOₓ, HfOₓ, AlOₓ, YOₓ, ScOₓ, MoOₓ, WOₓ, or VOₓ, and the solid-state doping layer comprises SiNₓ, HfNₓ, AlNₓ, YNₓ, or ScNₓ. The method further includes forming a gate dielectric layer over the first and second source/drain contacts and the channel regions of the plurality of nanostructures. The gate dielectric layer is formed prior to forming the solid-state doping layer. In some embodiments, the second portion of the solid-state doping layer comprises a vertical portion vertically extending between the gate electrode and the first source/drain contact, and a horizontal portion horizontally extending above the first source/drain contact. The third portion of the solid-state doping layer comprises a vertical portion vertically extending between the gate electrode and the second source/drain contact, and a horizontal portion horizontally extending above the second source/drain contact.

In some embodiments, the present disclosure provides a method that includes the formation of a first solid-state doping layer over a substrate. This method further involves disposing a plurality of nanostructures over the aforementioned nitride layer. Additionally, the method includes forming a first source/drain contact over the first source/drain regions of the nanostructures. A second source/drain contact is also formed over the second source/drain regions of the nanostructures. The method further comprises forming a gate electrode situated between the first and second source/drain contacts. The method further comprises forming an oxygen-vacancy-containing oxide layer over the first nitride-vacancy-containing nitride layer. In some embodiments, the plurality of nanostructures are disposed on the oxygen-vacancy-containing oxide layer. In some embodiments, the method further comprises forming a second solid-state doping layer over the first and second source/drain contacts, and the gate electrode; and removing a first portion of the second solid-state doping layer from a top surface of the gate electrode, while leaving a second portion and a third portion of the second solid-state doping layer over the first and second source/drain contacts, respectively. In some embodiments, the method further comprises forming an oxygen-vacancy-containing oxide layer over the first and second source/drain contacts prior to forming the second solid-state doping layer.

In some embodiments the present disclosure provides a device comprising a plurality of nanostructures over a substrate, a first source/drain contact over first source/drain regions of the nanostructures, a second source/drain contact over second source/drain regions of the nanostructures, a gate electrode between the first and second source/drain contacts, and a first solid-state doping layer overlapping with the first source/drain contact. In some embodiments, the device further comprises a second solid-state doping layer overlapping with the second source/drain contact, and a third solid-state doping layer between the nanostructures and the substrate. In some embodiments, the device further comprises an oxygen-vacancy-containing oxide layer between the first solid-state doping layer and the first source/drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
disposing a plurality of nanostructures over a substrate;
forming a first source/drain contact over first source/drain regions of the plurality of nanostructures;
forming a second source/drain contact over second source/drain regions of the plurality of nanostructures;
forming a gate electrode over channel regions of the plurality nanostructures;
forming a solid-state doping layer over the gate electrode, and the first and second source/drain contacts; and
removing a first portion of the solid-state doping layer from a top surface of the gate electrode, while leaving a second portion and a third portion of the solid-state doping layer over the first and second source/drain contacts, respectively.

2. The method of claim 1, further comprising:
forming an oxygen-vacancy-containing oxide layer over the first and second source/drain contacts.

3. The method of claim 2, wherein the oxygen-vacancy-containing oxide layer is formed prior to forming the solid-state doping layer.

4. The method of claim 2, wherein the oxygen-vacancy-containing oxide layer has a thickness less than a minimal thickness of the solid-state doping layer.

5. The method of claim 2, wherein the oxygen-vacancy-containing oxide layer is further formed over the gate electrode, and the method further comprises:
removing a first portion of the oxygen-vacancy-containing oxide layer from the top surface of the gate electrode, while leaving a second portion and a third portion of the oxygen-vacancy-containing oxide layer over the first and second source/drain contacts, respectively.

6. The method of claim 2, wherein the oxygen-vacancy-containing oxide layer comprises SiOₓ, HfOₓ, AlOₓ, YOₓ, ScOₓ, MoOₓ, WOₓ, or VOₓ.

7. The method of claim 1, further comprising:
forming a gate dielectric layer over the first and second source/drain contacts and the channel regions of the plurality of nanostructures.

8. The method of claim 7, wherein the gate dielectric layer is formed prior to forming the solid-state doping layer.

9. The method of claim 1, wherein the solid-state doping layer comprises SiNₓ, HfNₓ, AlNₓ, YNₓ, or ScNₓ.

10. The method of claim 1, wherein the second portion of the solid-state doping layer comprises a vertical portion vertically extending between the gate electrode and the first source/drain contact, and a horizontal portion horizontally extending above the first source/drain contact.

11. The method of claim 10, wherein the third portion of the solid-state doping layer comprises a vertical portion vertically extending between the gate electrode and the second source/drain contact, and a horizontal portion horizontally extending above the second source/drain contact.

12. A method comprising:
forming a first solid-state doping layer over a substrate;
disposing a plurality of nanostructures over the first solid-state doping layer;
forming a first source/drain contact over first source/drain regions of the plurality of nanostructures;
forming a second source/drain contact over second source/drain regions of the nanostructures; and
forming a gate electrode between the first and second source/drain contacts.

13. The method of claim 12, further comprising:
forming an oxygen-vacancy-containing oxide layer over the first solid-state doping layer.

14. The method of claim 13, wherein the plurality of nanostructures are disposed on the oxygen-vacancy-containing oxide layer.

15. The method of claim 12, further comprising:
forming a second solid-state doping layer over the first and second source/drain contacts, and the gate electrode; and
removing a first portion of the second solid-state doping layer from a top surface of the gate electrode, while leaving a second portion and a third portion of the second solid-state doping layer over the first and second source/drain contacts, respectively.

16. The method of claim 12, further comprising:
forming an oxygen-vacancy-containing oxide layer over the first and second source/drain contacts prior to forming the second solid-state doping layer.

17. A device, comprising:
a plurality of nanostructures over a substrate;
a first source/drain contact over first source/drain regions of the nanostructures;
a second source/drain contact over second source/drain regions of the nanostructures;
a gate electrode between the first and second source/drain contacts; and
a first solid-state doping layer overlapping with the first source/drain contact.

18. The device of claim 17, further comprising:
a second solid-state doping layer overlapping with the second source/drain contact.

19. The device of claim 17, further comprising:
a third solid-state doping layer between the nanostructures and the substrate.

20. The device of claim 17, further comprising:
an oxygen-vacancy-containing oxide layer between the first solid-state doping layer and the first source/drain contact.
